(19) United States
(12) Patent Application Publication
(10) Pub. No.: US 2010/0330787 A1
(43) Pub. Date: Dec. 30, 2010

(54) APPARATUS AND METHOD FOR ULTRA-SHALLOW IMPLANTATION IN A SEMICONDUCTOR DEVICE

(76) Inventor: Piero Sferlazzo, Marblehead, MA (US)

Correspondence Address: RAUSCHENBACH PATENT LAW GROUP, LLP, P.O. BOX 387, BEDFORD, MA, 01730, US

(21) Appl. No.: 12/377,825

(22) PCT Filed: Aug. 17, 2007
(86) PCT No.: PCT/US07/18273

§ 371 Date: Sep. 16, 2010

Related U.S. Application Data
(60) Provisional application No. 60/822,804, filed on Aug. 18, 2006.

(51) Int. Cl. H01L 21/265

(52) U.S. Cl. 438/514; 118/620; 118/722; 204/298.02; 204/298.16; 257/E21.334

(57) ABSTRACT

Methods and devices for forming an ultra-thin doping layer in a semiconductor substrate include introducing a thin film of a dopant onto a surface of the substrate and driving at least a portion of the thin dopant layer into a surface of the semiconductor. Gas ions used in the driving-in process may be inert to minimize contamination during the drive in process. The thin films can be deposited using know methods, such as physical deposition and atomic layer deposition. The dopant layers can be driven into the surface of the semiconductor using known techniques, such as pulsed plasma discharge and ion beam. In some embodiments, a standard ion implanter can be retrofit to include a deposition source.

### CROSS-REFERENCE TO RELATED PATENT APPLICATIONS

This application claims priority from U.S. Provisional Application Ser. No. 60/822,804, filed on Aug. 18, 2006, incorporated herein by reference in its entirety.

### FIELD OF THE INVENTION

The present invention relates generally to the field of ion implantation as used in a process of manufacturing devices such as semiconductor devices and, more particularly, to ion implantation in which a substantial concentration of dopant is implanted within an ultra-shallow layer of a semiconductor device.

### BACKGROUND OF THE INVENTION

Over the past thirty years, ion implantation has been a process of choice for the doping of semiconductor materials to form P/N junctions and transistors thereon. In a typical ion implanter, vapor materials including the implant species are ionized in an ion source. Ions of the implant species are extracted from the vapor and accelerated onto a target including one or more semiconductor substrates. Acceleration of the ions can be accomplished by a series of electrodes, magnets, and combinations of electrodes and magnets. In some applications, the arrangement of electrodes and magnets (e.g., sector magnets) can be used to selectively direct ions of a preferred mass and a preferred energy toward the target to be implanted therein.

More complex ion implanting configurations include one or more of a mass analyzer, acceleration electrodes, deceleration electrodes, shaping magnets, and scanning magnets. The target configurations include single or multiple semiconductor substrates, such as a semiconductor wafer and a mount, sometimes referred to as a chuck, or holder. In some applications, the mounts are configured with multiple axes of motion that enable uniform positioning and repositioning of the target with respect to exposure by the incoming ions. Such mobility allows the target to be positioned with respect to the source to allow wide variations of angles of incidence. Examples of prior art ion implanters are discussed in U.S. Pat. Nos. 4,276,477 issued Jun. 30, 1981; 4,283,631 issued Aug. 11, 1981 to Turner; 4,899,059 issued Feb. 6, 190 to Freytsis et al; 4,922,106 issued May 1, 1990 to Berrian et al.; and 5,350,926 issued Sep. 27, 1994 to White et al.

Trends in the semiconductor industry for over thirty years have largely kept pace with Moore's law. Namely, every two years performance of the semiconductor devices doubles while cost is reduced by on half. Consequently, devices get smaller and faster at each technological node. This means that lateral dimension of devices formed on semiconductor substrates have been getting smaller, and will continue to do so for the foreseeable future. Due to scaling of the electrical properties of the devices, vertical depths of devices continue to get shallower. At present, junction depths are rapidly approaching the 20 nm dimensions.

This trend for smaller devices with shallower depths has lead to a reduction in overall energy applied in most of the ion implant steps. In particular the source and drain regions of devices of physically small devices require a very high dose at relative low energy (e.g., sub KeV energies), in order to form ultra shallow junctions.

Unfortunately, ion transport of low energy ions through an implanter beam line is very difficult and inefficient. Electrical currents associated with ion implanters degrade very rapidly below 10 KeV. For example, while a typical B current at 20 KeV is more than 15 mA, the same current when operated below 1 KeV could be reduced to less than 2 mA. Since the dose of these ultra shallow junction source/drain implant remain relatively high (e.g., on the order of 1×10¹⁵ atom/cm²), the implantation time is extended. Such delays in processing will tend to substantially increasing the device costs.

The cause of such a dramatic reduction in current at low energy levels is mainly due to depletion of the beam resulting from space charge effects. One solution to the problem has traditionally been to transport the ion beam at high energy and then to decelerate the ion beam to a desired lower energy level just in front of the substrate. Although such an approach can be effective in increasing the ion current seen by the substrates, it suffers from a fundamental flaw. Since the deceleration has to be in line of site of the substrate, charge exchange reactions with the residual gas in the beam line will lead to a substantial number of high-energy, neutrally charged particles. The high energy neutral particles will remain unaffected by the deceleration electrode and will be implanted into the substrate in conjunction with the low energy ions. Such high energy contamination is generally unacceptable. In addition, the high energy contamination is highly sensitive to the residual gas pressure and to the hard-to-control outgassing from chamber walls and substrates. Accordingly, repeatability of any such process would be very difficult to say the least.

In the past ten years, a number of alternative high-dose, shallow junction approaches have been proposed to overcome these difficulties. One such alternative approach that has achieved limited adoption is plasma doping. In plasma doping the substrate is mounted on a conductive chuck and immersed in a plasma produced by any of various known discharge methods, such as radiofrequency (RF), microwave, and direct current (DC). A plasma volume or sheet including ions of a dopant species is created proximal to a target surface of a semiconductor substrate. A high potential difference is introduced between the plasma and the substrate to accelerate ions across the sheet and implant them into the substrate. For example, a high-voltage negative pulse can be applied to the substrate chuck for implanting ions into the substrate.

Such plasma techniques suffer from at least two major problems that have tended to limit their adoption. First, without mass separation, all the species in the plasma are implanted simultaneously into the substrate. Thus, many unwanted atoms may be implanted together with the intended doping atoms. Such unwanted atoms may result from contaminants from residual gases in the chamber and sputter materials from the chamber walls. Second, the plasma sheath thickness at the required plasma densities is much larger than the feature dimensions on the substrate. Accordingly, ions accelerated across the sheath are generally perpendicular to the substrate surface. Therefore, it is generally very hard to dope side walls and other surfaces that are not parallel to the plasma sheath. Exemplary plasma doping systems are described in U.S. Pat. Nos. 5,354,381 issued Oct. 11, 1994 to Sheng; 6,020,592 issued Feb. 1, 2000 to Liebert et al; and 6182,604 issued Feb. 6, 2001 to Goeckner et al.

Another technique currently being investigated is cluster implantation. Cluster implantation uses large molecules, having multiple atomic species or atomic clusters. These large molecules are transported at high energies through the ion implanter and toward the target. Because of their larger mass, the penetration depth of the large molecules is shallow. Also, because of their size, the dose is high—a large number of doping atoms in the cluster. The industry has been slow in adopting this technique, however, due to the cost of specialized equipment that is required, concerns about damage to the substrate, and contamination from the unwanted atomic species which form the cluster or large molecule.

### SUMMARY OF THE INVENTION

There is a need for a cost effective technique for high-dose, shallow doping, which is compatible with the present tools set and that overcomes the problems associated with the present state of the art.

Beneficially, the present invention introduces a thin layer (typically between about 1 and 100 Å) of doping material deposited onto a semiconductor substrate. Following the formation of the thin coating, the substrate is exposed to energetic gas ions, which may be inert gases such us argon (Ar) or xenon (Xe). The energetic ions collide with the doping atoms at the surface creating cascades which penetrate the substrate. Since the energy of the ion is shared by a large number of collisions, the penetration depth of the recoiling doping atoms is relatively low, thus creating a very shallow doped region.

One embodiment of the invention relates to processing semiconductor substrates. A thin layer of a dopant is deposited onto a surface of the semiconductor substrate. Ions of a gas are energized and directed in a beam toward the surface of the semiconductor substrate. Kinetic energy is transferred from the beam of energized ions to the thin layer of the dopant. Consequently, a portion of the thin layer of dopant is implanted into the semiconductor substrate. By controlling kinetic energy of the ion beam and thickness of the thin film layer of dopant, an ultra-shallow doped layer is formed within the semiconductor substrate.

Another embodiment of the invention relates to a device for processing a semiconductor substrate. The device includes a processing chamber and a semiconductor substrate mount configured to support a semiconductor substrate for processing within the chamber. The device also includes a deposition source configured to form a thin layer of a dopant on a surface of the semiconductor substrate. An ion accelerating source in fluid communication with a gas source is configured to produce a directional ion beam. The ion accelerating source is configured to direct a beam of ions of the gas toward the surface of the semiconductor substrate. Once again, the gas can be an inert gas and its kinetic energy transferred from the beam of ions directed toward the thin layer of the dopant. Consequently, a portion of the thin layer of dopant is implanted into the semiconductor substrate. By controlling kinetic energy of the ion beam and thickness of the thin film layer of dopant, an ultra-shallow doped layer is formed within the semiconductor substrate.

Another embodiment of the invention relates to processing semiconductor substrates. An ultra-thin layer of substantially pure dopant is deposited onto a surface of the semiconductor substrate. A beam of substantially inert ions is directed toward the ultra-thin layer deposited on the surface of the semiconductor substrate. Kinetic energy is transferred from the beam of substantially inert ions to the ultra-thin layer of dopant, the transfer of energy driving at least a portion of the ultra-thin layer of dopant into the semiconductor substrate. A controlled level of kinetic energy of the ion beam and thickness of the ultra-thin film layer of dopant, forms an ultra-shallow doped layer within the semiconductor substrate.

Another embodiment of the invention relates to a device for processing a semiconductor substrate. The device includes means for depositing a thin layer of a dopant onto a surface of the semiconductor substrate. The device also includes means for energizing ions of a substantially inert gas and means for directing a beam of energized ions toward the surface of the semiconductor substrate. Means for transferring kinetic energy from the beam of energized ions to the thin layer of dopant implant at least a portion of the thin layer of a dopant by a transfer of energy into the semiconductor substrate.

Yet another embodiment of the invention relates to processing semiconductor substrates. An ion source is provided including a processing chamber. The ion source is configured to produce a directed ion beam. A thin film deposition source is provided within the processing chamber. The deposition source is configured to deposit a thin layer of a doping species onto a surface of a semiconductor substrate. The directed ion beam is adapted to implant at least a portion of the thin layer of the doping species into the semiconductor substrate when the substrate is positioned within the directed ion beam.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a flow diagram of an exemplary embodiment of a semiconductor process according to the present invention.

FIG. 2A through FIG. 2D are schematic diagrams illustrating in cross sectional elevation view, various stages of an atomic layer deposition upon a semiconductor substrate.

FIG. 3A is a schematic view of an embodiment of an ultra-shallow semiconductor doping system according to the present invention, with a semiconductor substrate positioned for thin film deposition.

FIG. 3B is a schematic view of the ultra-shallow semiconductor doping system illustrated in FIG. 3A, with the semiconductor substrate positioned for ion implantation.

FIG. 4 is a schematic view of an alternative embodiment of an ultra-shallow semiconductor doping system according to the present invention.

FIG. 5 is a schematic view of yet another alternative embodiment of an ultra-shallow semiconductor doping system according to the present invention

FIG. 6A through FIG. 6D are schematic diagrams illustrating in cross sectional elevation view, various stages of a sequence for doping a semiconductor substrate according to the present invention.

FIG. 7 is a schematic diagram illustrating in cross sectional elevation an exemplary embodiment of an ultra-shallow semiconductor doping system having a tiltable semiconductor chuck.

### DETAILED DESCRIPTION OF THE PREFERRED EMBODIMENTS

Beneficially, the present invention introduces a thin layer (typically between about 1 and 100 Å) of doping material deposited on a semiconductor substrate. Following the formation of the thin coating, the substrate is exposed to energetic gas ions, which can be an inert gas such us argon (Ar) or xenon (Xe). The energetic ions collide with the doping atoms at the surface creating cascades which penetrate the substrate. Since the energy of the ion is shared by a large number of collisions, the penetration depth of the recoiling doping atoms is relatively low, thus creating a very shallow doped region. Deposition of the thin layer can be achieved using any of a number of available techniques. For example, the thin layer of doping material can be obtained using sputtering, evaporation, chemical vapor deposition, simple exposure of the substrate to the appropriate gaseous material, and combinations thereof.

At the same time, some of the recoiling atoms escape the surface as sputtered atoms. The coating thickness is a critical parameter. If it is too thick the recoiling atoms do not reach the bulk material, if it is too thin, sputtering etches the coating and no doping occurs. To be effective, the deposition apparatus must be located within the ion implant chamber. In a typical sequence the process consists of multiple deposition steps each followed by an implantation step as shown and described herein.

In some embodiments of the invention, a deposition apparatus can be easily retrofitted into a standard ion implanter, providing customer with a cost effective solution which makes efficient use of their tool set. For example, the process described herein can be implemented using a modified standard atomic layer deposition chamber or a continuous flow atomic layer deposition system as described in U.S. Pat. No. 6,672,055, incorporated herein by reference in its entirety.

Other benefits of the invention include minimizing contamination, since the doping material can be deposited with high purity. Also, since deposition can be quite conformal over steps and valleys of the substrate surface, it is particularly well suited for such samples. It may be necessary, however, to use multiple implant angles to drive in the dopant and so dope any side walls and non flat regions of the substrate.

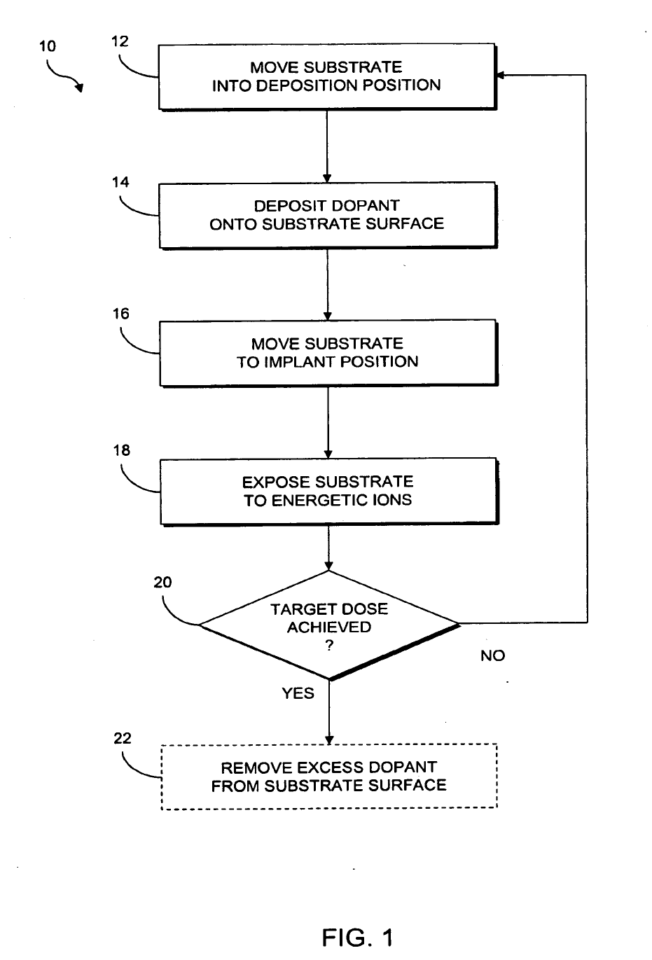

Referring to FIG. 1, a flow diagram is shown of an exemplary embodiment of a semiconductor process according to the present invention. In the exemplary four-step drive-in doping process, a semiconductor substrate is suitably positioned for a deposition mode at Step 12. A particular position if the substrate depends to some degree upon the method of deposition selected. For sputtering deposition, the substrate is positioned to intercept a dopant flux emitted from a sputtering source.

Once positioned, a dopant material is deposited onto a surface of the semiconductor substrate at Step 14. Such a process is commonly referred to as thin-film deposition. There are numerous method of thin film deposition that may be employed either alone or in combination. Some exemplary thin film deposition processes include: physical vapor deposition (PVD); chemical vapor deposition (CVD); electrochemical deposition (ECD); molecular beam epitaxy (MBE); e-beam evaporation; sputtering; atomic layer deposition (ALD). Depending upon the particular deposition method chosen and the size of the substrate, it may be necessary to move the substrate with respect to the deposition source to obtain uniform and complete coverage.

In some embodiments, a deposition process is selected to provide a conformal and substantially uniform coating. One process well suited for such conformal coating is atomic layer deposition. Preferably, the thin film layer deposited is between about 1 and 100 Å. In some embodiments, the thin film layer can be applied as a monolayer, or slightly thicker than a monolayer of atoms or molecules of the dopant. A monolayer contains approximately 1×10¹⁵ molecules/cm². The deposition flux can be collimated into a substantially linear uniform shape and deposition uniformity of the deposition is achieved by translating the substrate across said deposition flux. Exemplary dopants include: antimony; arsenic; arsine; phosphorus; phosphine; and boron.

Once the thin film has been applied, the coated substrate is moved into a position suitable for implantation mode at step 16. Such positioning can be accomplished by moving the substrate with respect to a stationary ion source, moving a repositionable ion source with respect to a stationary substrate, or some combination of moving both the ion source and the substrate. Such positioning of substrates is generally known to those skilled in the art of semiconductor fabrication and wafer handling.

Once positioned, an energized beam of ionized particles is directed onto the coated surface of the semiconductor substrate at Step 18. The ionized particles can be accelerated by an ion source, such as an ion implanter, toward the substrate. In another embodiment, they may be implanted by a pulsed plasma. Depending upon the mass of the ion species and the associated kinetic energy, the accelerated ions collide with the atoms or molecules of the substrate coating (e.g., dopant layer). In some embodiments, the ion beam is a slit beam, and implant uniformity is achieved by translating the substrate across said slit beam. In other embodiments, the ion beam is substantially circular in shape and implant uniformity is achieved by translating the substrate in two directions of motion. The collisions results in a transfer of at least some of the energy of the ions to the dopant layer, causing the atoms or molecules of the dopant layer to travel to a depth within the semiconductor substrate in a process referred to as implantation. Depending upon such control parameters as the acceleration of the ions, their mass, and a depth of the dopant coating layer, at least a portion of the dopant atoms or molecules are implanted forming an ultra-shallow doped region. Ultra-shallow generally means less than 500 Å and preferably less than 100 Å.

Typically, a doped region includes a preferred density or concentration of dopant atoms or molecules (e.g., 1×10¹⁵ atoms/cm²). In prior art systems, this density can be controlled by a dosage. However, using ultra-thin conformal layers, there may be insufficient dopant atoms or molecules within the layer to achieve the desired concentration. Any technique suitable for determining a density or concentration of dopant during ion implantation may be used. Such techniques are generally well known to those skilled in the art of semiconductor fabrication.

The determined dopant concentration can be compared to a target or threshold value at Step 20. If the dopant concentration is below the target or threshold, Step 12 through Step 18 are repeated. Such repetition can continue as many times as necessary to achieve the desired dopant concentration. Once a sufficient dopant concentration has been achieved, the process can conclude. For applications using a monolayer of about 1×10¹⁵ molecules/cm² and assuming that only about 1% of the dopant is driven into the wafer at each cycle, it would take about 100 cycles to achieve the desired dose, assuming a typical dose requirement of about 1×10¹⁵ atoms/cm².

More generally, the process illustrated in FIG. 1 can be performed in a continuous manner or in discrete steps. For example, movement of the substrate can be accomplished using constant velocity motion. Deposition and Ion beams can be configured to provide a footprint on a target, such as an oblong or columnar footprint. Travel of the substrate through such a footprint at constant velocity will be conducive to forming uniform coating through deposition and uniform implanting for ion implantation. Thus, the substrates can remain in motion through all or at least some of the different process steps in a continuous' manner.

Optionally, the substrate can be treated to remove excess dopant remaining on the surface of the substrate at Step 22. Such removal or etching may be required if further processing of the semiconductor wafer is necessary. In some embodiments, excess dopant is removed from the surface between each repetition of Step 12 through Step 18 to ensure uniformity of the ultra-thin deposited layer. Alternatively or in addition, the coating step can be performed simultaneous with the implantation, exposing the surface to the doping material while being exposed to the ion beam.

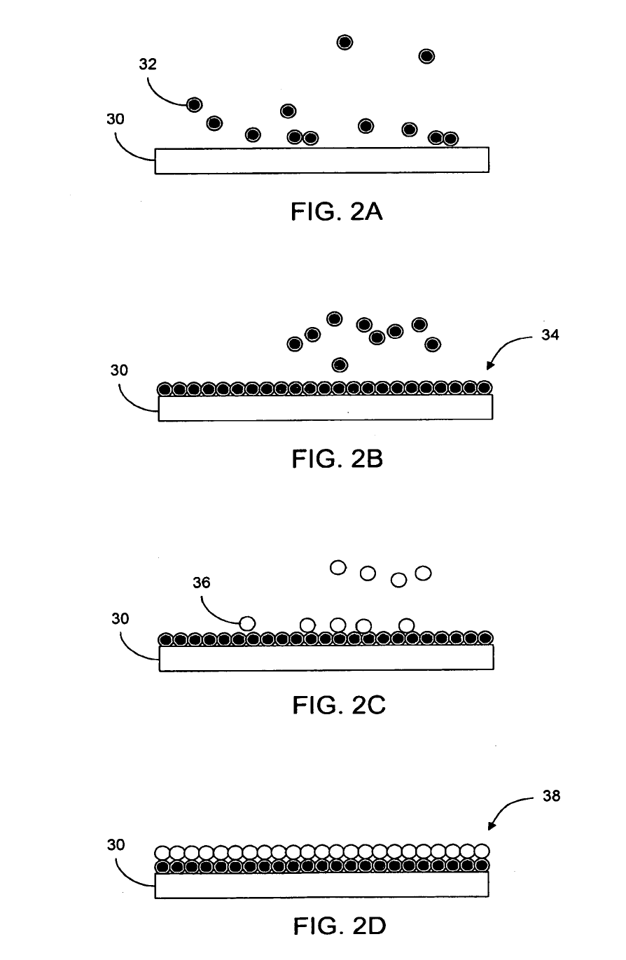

Referring to FIG. 2A through FIG. 2D, schematic diagrams are shown illustrating in cross sectional elevation view, various stages of a process for depositing an atomic layer upon a surface of a semiconductor substrate. In a first step of the process shown in FIG. 2A, a surface of the semiconductor substrate or wafer 30 is exposed to a precursor A containing a dopant species 32. In a second step of the process shown in FIG. 2B, the chamber is purged to remove excess dopant species 32 and any other impurities that may be present. In a third step of the process shown in FIG. 2C, the wafer is exposed to precursor B 36, which reacts with precursor A 32 to form an ultra-thin layer 38 on the surface of the wafer 30 as shown in FIG. 2D. An ultra-thin layer formed in this manner will tend to conformally coat the surface. In some applications, the ultra-thin layer is substantially a monolayer. The ultra-thin layer can be driven into the surface of the wafer 30 using a number of techniques, such as thermal drive-in or diffusion; laser drive-in, pulsed plasma, and standard ion beam techniques. For drive-in plasma or ion beams with mass and energy selection (e.g., monoenergetic), the depth of profile can be quite sharp and substantially uniform.

Beneficially, since the initial surface concentration of the dopant is uniform and conformal, the doping dose will also be uniform and, at least to a first order, independent of the specific characteristics of the plasma. Additionally, since only an ultra-thin layer at a time is exposed to the plasma or ion beams, lower beam energies are required (e.g., less than 1 KeV). Beneficially, lower beam energies result in less damage to the surface of the wafer 30, thereby reducing the need for temperature anneals.

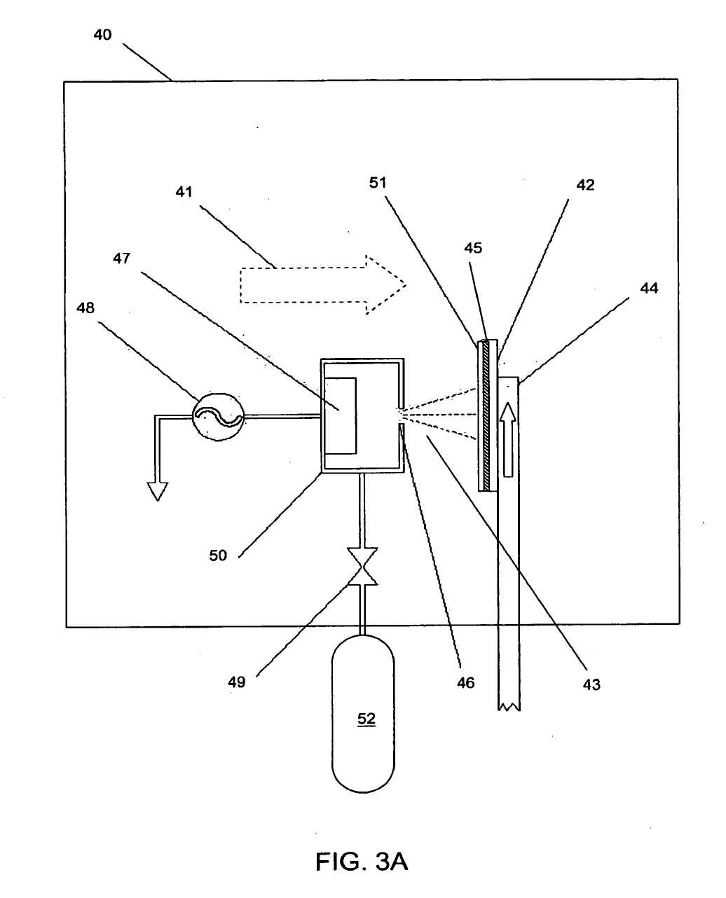

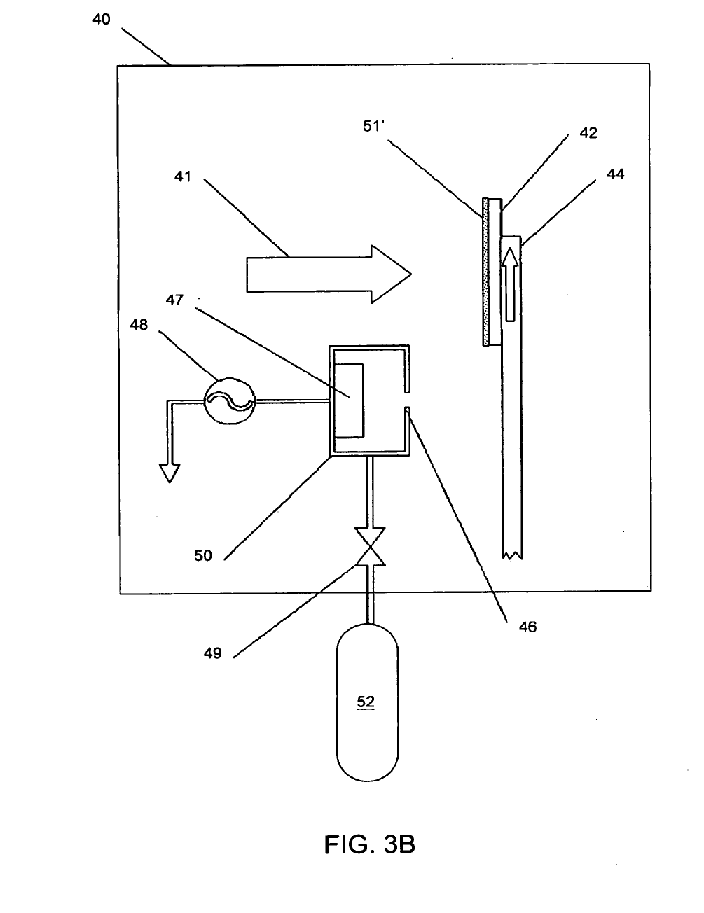

Referring to FIG. 3A a schematic view is shown of an embodiment of an ultra-shallow semiconductor doping system according to the present invention, with a semiconductor substrate positioned for thin film deposition. The exemplary system includes a processing chamber 40 including a mount or chuck 42 for holding a semiconductor substrate 45. The chuck 42 can be electrostatic and adapted to hold a semiconductor substrate thereon through electrostatic attraction. Alternatively or in addition, the chuck 42 can be vacuum actuated and adapted to hold the semiconductor substrate thereon through negative pressure. The system also includes within the same processing chamber 40, a thin-film deposition source 50 and an implantation source 41. In an illustrative embodiment, the thin-film deposition source is a magnetron sputtering device 50 and the implantation source is a serial high current ion implanter 41. In the exemplary configuration, the magnetron sputtering device 50 and the serial high current ion implanter 41 are spaced apart and each aimed in a substantially parallel direction with respect to the other.

The system also includes a mechanical linkage configured to move the chuck 42 relative to the sources 50, 41. The mechanical linkage can be a rigid member 44 coupled at one position to the chuck 42 and at another position to an actuator (not shown). The actuator controls movement of the chuck 42 through the rigid member or linkage 44 such movement can be used to sequence a semiconductor substrate mounted on the chuck 42 between thin-film deposition mode and ion implantation mode. As shown in the illustrative example, a semiconductor substrate mounted on the chuck 42 is positioned such that a surface of the semiconductor substrate is sequentially exposed to a dopant flux 43 from the sputtering device 50 and an ion beam from the ion implanter 41. In some embodiments the actuator and mechanical linkage 44 are configured to move the chuck 42 in a linear and reciprocating manner. A controller, not shown, can be used to control the actuator to ensure that a semiconductor substrate mounted on the chuck 42 is moved according to a predetermined process sequence.

For example, under the direction of the controller, the actuator moves a semiconductor substrate 45 linearly in an upward direction as illustrated by the vertical arrow. Preferably, the chuck 42 is moved at a constant velocity across the dopant flux 43 from the magnetron sputtering device 50. Uniformity of exposure is therefore achieved by moving the substrate 45 linearly in front of the beam, with constant velocity from the two over-scan positions.

In the exemplary embodiment, the ion beam produced from the ion source 41 is a stationary slit beam, shown side view in the figure. The chuck 42 holds the substrate 45 and is attached by the mechanical linkage 44 to the actuator. The actuator is configured to move the chuck 42 linearly in front of the beam 41. Uniformity of exposure is therefore achieved moving the substrate 45 linearly in front of the beam 41 and moving with constant velocity between the two positions.

In a first of the two position, the chuck 42 is extended to place the substrate 45 in a deposition mode. In the deposition mode, as shown, the substrate 45 is positioned to receive a deposition of a thin film from the deposition source 50. In some embodiments, the deposition source 50 includes a deposition volume 50 that is separated from the processing chamber 40 by a restricted aperture. For example, the restricted aperture can be a pin hole or a substantially linear slit 46, shown along a narrow dimension. In most applications, and particularly when the implantation source is an ion source 41, the process chamber 40 will be evacuated to a first pressure. Depending upon the particular selection of deposition source, the deposition volume may be maintained at a differential pressure with respect to that of the process chamber 40.

In some embodiments, the physical vapor deposition apparatus and the process chamber are separated by one or more apertures creating a substantial pressure differential between the process chamber and the physical vapor deposition apparatus. The one or more apertures can be collimating apertures configured to shape the deposition flux is a substantially linear shape.

In one particular embodiment, the deposition source 50 uses sputtering to deposit a thin film of dopant on a surface of the substrate 45. A common sputtering source is a magnetron. For example, a substantially linear sputtering magnetron 57 is placed inside the deposition volume 50. The magnetron 57 is energized by a power supply 48. In some embodiments, the power supply 48 can be a pulsed-DC power supply. Alternatively or in addition, the power supply 48 can be an RF power supply. Whether the power supply 48 is pulsed DC or RF generally depends on whether the target material is conducting or insulating.

For a linear slit sputtering source 50, a target surface of the substrate 45 is placed a distance away from the slit 46 and substantially parallel to the slit 46. The sputtering source 50 is in fluid communication with a sputtering, or magnetron gas source 52. At least one gas commonly used in magnetron sputtering application is argon. Preferably, the magnetron gas source 52 is coupled to the deposition volume 50 through a fast actuating valve 49. The fast acting valve 49 can be configured to turn the magnetron gas supply on during a deposition phase and off during an implantation phase.

In a deposition phase, the fast acting valve 49 is opened such that the magnetron gas source 52 is in fluid communication with the deposition volume. Also in the deposition phase, the power supply 48 is turned on to energize the magnetron 47. In the deposition mode, a deposition flux 43 is produced extending away from the slit 46 and into the processing chamber 40. A substrate 45 placed in a path of the deposition flux 43 will be coated with a thin film layer of the dopant material.

Referring to FIG. 3B, a schematic view is shown of the ultra-shallow semiconductor doping system is illustrated in an ion implantation phase. In this phase, the fast acting valve 49 is closed and the power supply 48 is de-energized, such that the deposition source 50 is turned off. The ion source 41 is activated to energize selected ions and to direct the energized ions in a beam as illustrated by the arrow of the source 41. To accomplish implantation of the dopant material, the substrate 45 with its thin film 51 deposited along a surface is positioned to intersect the ion beam 41. This positioning can be accomplished by using the mechanical linkage 44 to translate the substrate 54 towards an upper position as indicated by the vertical arrow. As the energized ions strike the thin film 51, they transfer at least a portion of their kinetic energy to the dopant atoms or molecules of the deposited layer 51 causing at least a portion of the dopant atoms or molecules to travel to a depth within the semiconductor substrate 45. The mass and energy of the ions can be controlled by the ion source 41 to implant dopant to a predetermined depth. Preferably, the implantation depth is shallow. For example, the implantation depth is preferably less than 500 Å. More preferably, the implantation depth is less than 100 Å.

As described above, the deposition source and ion source are directed toward different target positions. In order to act upon a common target, the target is positioned on a translatable chuck that moves the target as required between deposition phase and an implantation phase. A single sequence from deposition phase to implantation phase will result in a doping of a first dosage or concentration within the semiconductor substrate. If this dopant concentration is less than a target concentration level, the sequence can be repeated on or more times in order to achieve a desired doping concentration. Thus, the semiconductor wafer having a first implantation layer can be translated to a lower position, the ion source turned off and the deposition source 50 re-energized. This will deposit a second layer of dopant over the already doped semiconductor 45. The deposition source 50 can be de-energized, the substrate 45 translated to an upper position and the ion source re-energized to implant more dopant atoms. The process can be repeated as many times as necessary to build up the dosage to a desired level.

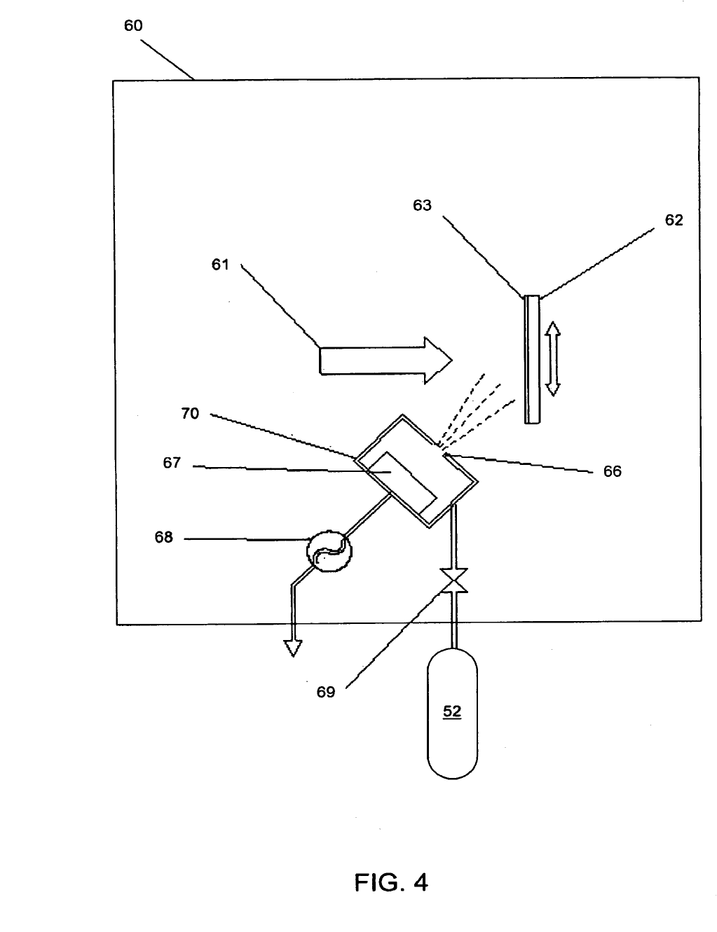

Referring to FIG. 4, a schematic view is shown of an alternative embodiment of an ultra-shallow semiconductor doping system according to the present invention. In this embodiment, a common processing chamber includes a deposition source 70 and an ion source 61. As in the previous example, the deposition source 70 can be a sputtering source having a deposition source volume 70 and a magnetron 67 included therein. The magnetron 67 is coupled to a magnetron gas source 52 through a fast-acting valve 69 and to a power supply 68. At least one of the deposition source 70 and the ion source 61 are angled with respect to the other, such a direction of deposition flux emerging from a slit 66 in the deposition source 70 intersects with an ion beam from the ion source 61.

The target semiconductor 63 is positioned within a plane including intersection of the paths, such that the substrate 63 in this position provides a suitable target for either of the deposition source 70 or the ion source 61, or both of the deposition source 70 and ion source 61. In other words, the thin film deposition, or coating phase, and the implantation phase each occur with the target semiconductor 63 in substantially the same location. In some embodiments, the deposition source 70 and the ion source 61 are energized and de-energized in an alternate fashion, such that an any instant of time, no more than one of the two sources 70, 61 is energized. In other embodiments, the deposition source 70 and the ion source 61 are energized simultaneously such that the target is coated and implanted at substantially the same location and at the same time. In any of the above embodiments, it may be necessary to move the substrate 63 with respect to the sources 70, 61 to ensure even and complete doping layer across a desired region of the surface of the semiconductor substrate. In some embodiments, one or more of the sources 70, 61 can be steerable. Such beam steering may be accomplished with beam steering techniques know in the art such as using combinations of one or more of electrodes and magnets. With such steerable sources, motion of the substrate may be unnecessary.

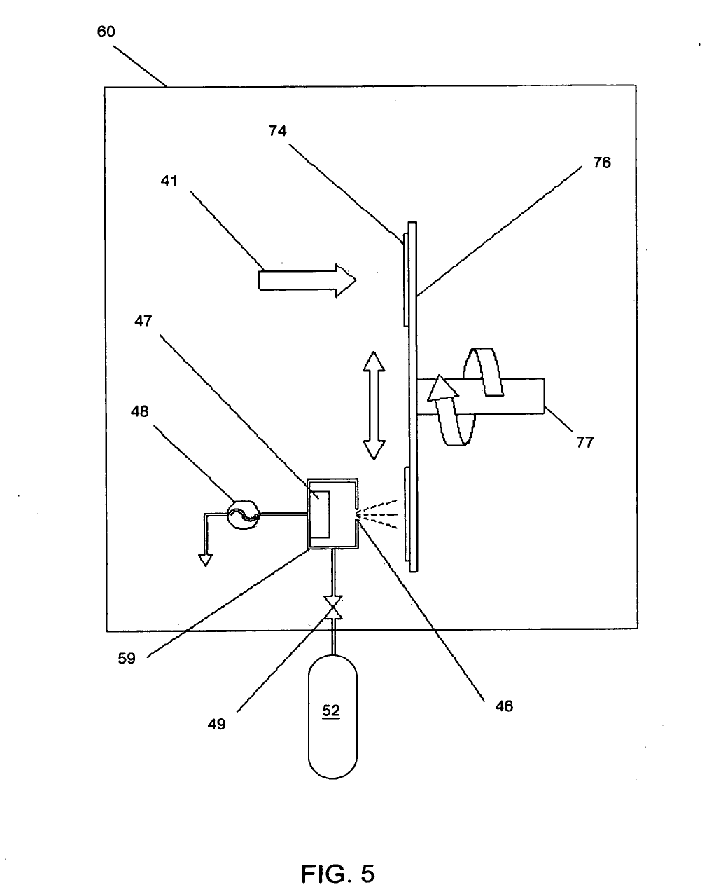

In some embodiments, multiple substrates are placed with the process chamber simultaneously for batch implantation. Referring to FIG. 5, a schematic view is shown of an exemplary embodiment of a batch processing, ultra-shallow semiconductor doping system. More than one substrate 74 are placed on a handling system 76 configured to move each of the substrates 74 between the different sequences of the process: deposition phase and implantation phase. For example, the handling system 76 includes a large disk 76 positioned in a plane substantially perpendicular to a plane containing both a deposition source 59 and an ion source 41. Multiple substrates can be placed on the disk 76 and positioned about a circumference of the disk 76. The disk 76 is rotatable about a central axis 77 Rotation of the disk 76 sequentially positions each of the multiple substrates 74 in front of the deposition source 59, which is stationary, and in front of the ion beam source 41, which is also stationary.

To expedite batch processing, spacing between the sources 41, 59 and between different ones of the multiple substrates 74 can be such that while one substrate is in the deposition phase, a different substrate is in the ion implantation phase as shown. In some embodiments, the entire disk 76 is translatable linearly in at least one direction as indicated by the vertical arrow. Thus, the substrates 74 can be scanned in front of each of the respective sources 41, 59 to ensure complete and even coverage. The combination of linear motion and rotation has proven to be a very effective technique to achieve good uniformity of exposure to the ion beam. As shown, the deposition source 59 can be placed along a circumference of the disk 76 away from the ion source 41, in a location that does not interfere with the ion beam. At each rotation of the disk 76, a small amount of doping material is deposited onto one of the substrates 74, while an already deposited layer is implanted in a different one of the substrates 74. The sequence can be repeated as many times as required to achieve a desired concentration of implanted atoms.

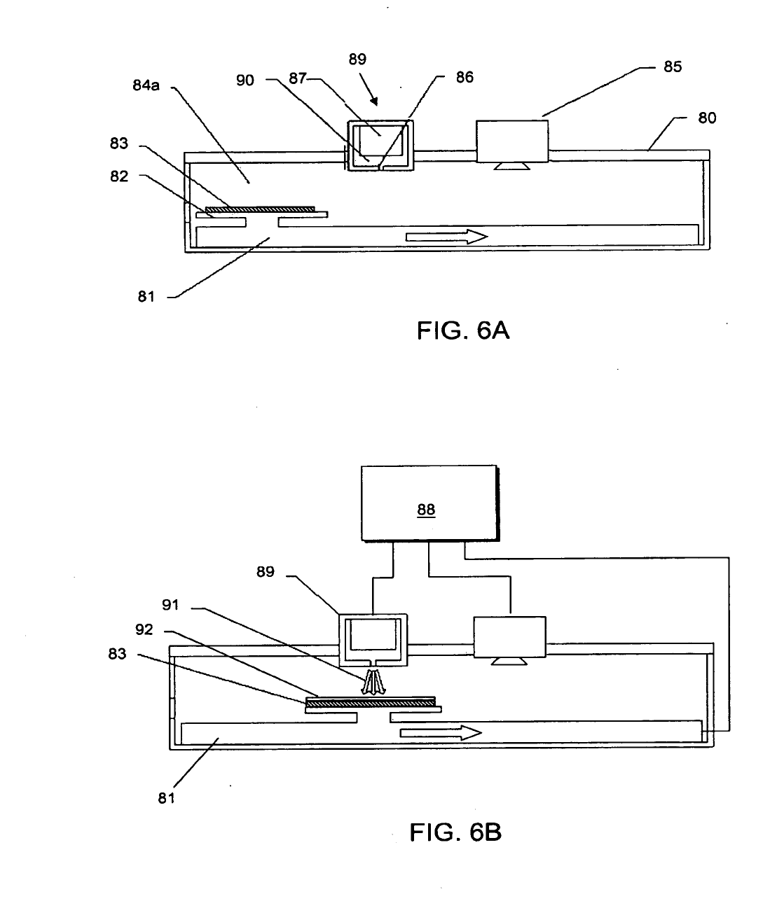

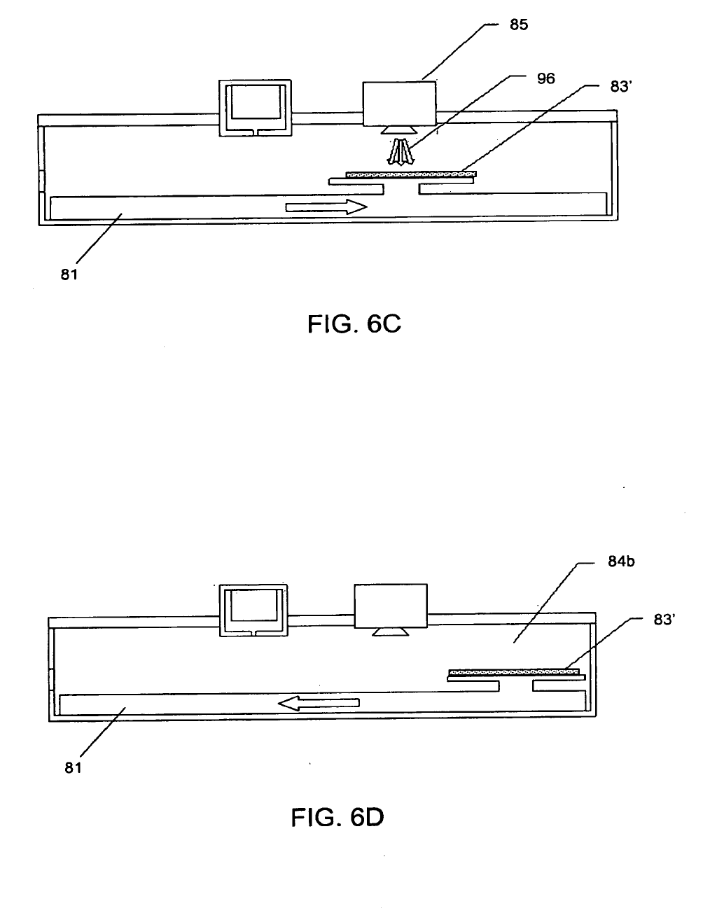

Referring to FIG. 6A through FIG. 6D, schematic diagrams are shown illustrating in cross sectional elevation view, various stages of a sequence for doping a semiconductor substrate according to the present invention. A process chamber 80 includes a stationary deposition source 89 and a stationary ion source 85. The deposition source 89 can be a linear sputtering source including a magnetron 87 positioned in a deposition chamber 90 with an access aperture 86 to the process chamber 80.

A semiconductor substrate 83 is mounted on a moveable chuck 82. The chuck 82 is configured to securely hold the substrate 83 and is attached to a motion system 81. The substrate 82 traverses across a deposition flux from the deposition source 89 and a directed beam of energized particles produced by ion source 85. Uniformity of exposure to the doping material 91 and the ion beam 96 is achieved by moving the substrate 82 with a constant velocity and in a linear direction past the ion source 15 and deposition source 89 while traversing between two over-scan positions 84a, 84b.

Control of one or more elements of the system can be accomplished manually or automatically under the operation of a control processor 88. For example, the control processor 88 is in electrical communication with at least the deposition source 89, the ion source 85, and the motion system 81. The controller 88 controls motion of the substrate by controlling the motion system 81. Such controls may include start, stop, velocity, and direction commands to a servo-controlled motion system 81. The controller 88 can control the sources 89, 85 to selectively and individually turn them on and off as required during the course of processing. The simple step of turning a source on or off may include a number of finer commands, such as operating a gas flow valve (not shown) and a power supply (not shown) connected to the magnetron 87.

FIG. 6A shows the substrate 83 in a first over-scan position 84a. Both sources 89, 85 are turned off. FIG. 6B shows the substrate 83 traveling beneath the deposition source 89, which is shown as being energized and producing a flux of doping material directed toward the substrate 92. The doping process produces an ultra-thin layer of dopant material 92 on a surface of the substrate 83. FIG. 6C shows the substrate 83′ traveling beneath the ion source. The deposition source 87 can be turned off. An ion beam 96 from the ion sources implants at least a portion of the layer of dopant material 92 to produce a doped semiconductor 83′. FIG. 6D shows the substrate 83′ in a second over-scan position 84b. The ion source 85 can also be turned off as shown. In either of the over-scan positions 84a, 84b, the motion system 81 moves the substrate completely out of any deposition flux 91 or ion beams 96.

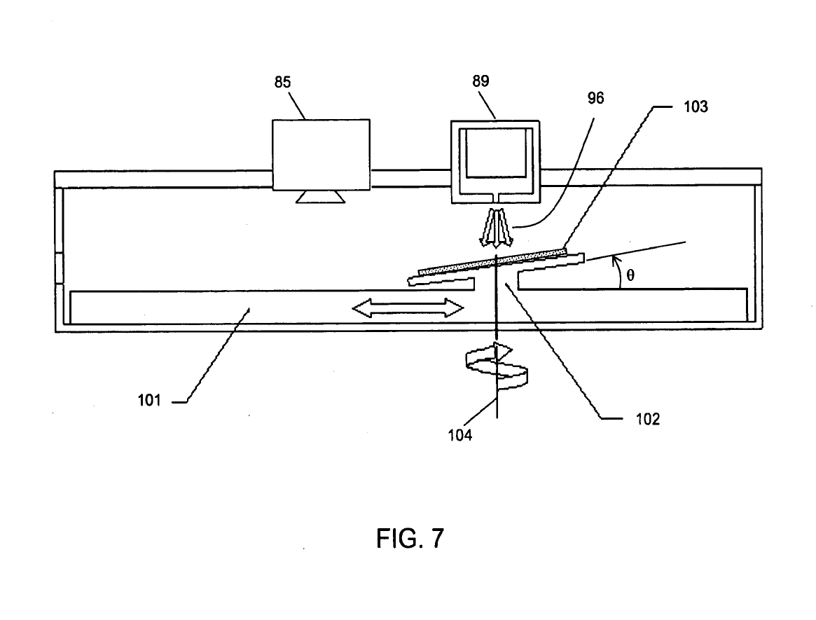

Referring to FIG. 7, a schematic diagram is shown illustrating in cross sectional elevation an exemplary embodiment of an ultra-shallow semiconductor doping system having a tiltable semiconductor chuck. A chuck 102 is mounted to a motion system 101 through a mechanical linkage that allows the chuck to move in one or more degrees of freedom. For example, the chuck 102 can be made to translate along a horizontal direction 101, rotate about a vertical axis 104, and tilt at an angle θ with respect to the horizontal plane. Such positional freedom is particularly useful in providing coverage in a deposition phase and in forming a uniform deposition layer by driving in atoms or molecules of the conformal layer along wells or steps that may not be parallel to a surface of the substrate 103.

In addition to the magnetron sputtering deposition sources described above, other vacuum compatible physical vapor depositions techniques such as evaporators or ion beam deposition.

In the case that doping materials that are volatile, the deposition means may not require a physical vapor deposition source. At a given temperature, volatile gases 12 can physisorb or chemisorb to the surface of the substrates 3 forming a one or more monolayers of the materials to be implanted (FIG. 2D).

The present invention may be embodied in other specific forms without departing from the spirit or essential characteristics thereof. The presently disclosed embodiment is therefore to be considered in all respects as illustrative and not restrictive, the scope of the invention being indicated by the appended claims, rather than the foregoing description, and all changes which come within the meaning and range of equivalency of the claims are, therefore, to be embraced therein. All references cited are hereby incorporated herein by reference in their entirety.

What is claimed is:

1. A method for processing a semiconductor substrate comprising:
a. depositing a thin layer of a dopant onto a surface of the semiconductor substrate;
b. energizing ions of a gas;
c. directing the energized ions in a beam toward the surface of the semiconductor substrate; and
d. transferring kinetic energy from the beam of energized ions to the thin layer of the dopant, wherein at least a portion of the thin layer of the dopant is implanted into an ultra-shallow doped layer within the semiconductor substrate by the transfer of the kinetic energy.

2. The method of claim 1, wherein the gas is substantially inert.

3. The method of claim 1, further comprising:
a. determining a dosage level of the dopant implanted into the semiconductor substrate;
b. comparing the determined dosage level to a target dosage level;
c. repeating the acts of depositing a thin layer of the dopant and directing the energized ions in an ion beam in succession responsive to the determined dosage level being less than the target dosage.

4. The method of claim 1, wherein the act of depositing the thin layer of the dopant comprises thin film deposition technique selected from the group consisting of: physical vapor deposition (PVD); chemical vapor deposition (CVD); electrochemical deposition (ECD); molecular beam epitaxy (MBE); e-beam evaporation; sputtering; atomic layer deposition (ALD), and combinations thereof.

5. The method of claim 1, wherein the ultra-shallow doped layer comprises a depth measured from the semiconductor surface of less than about 500 Å.

6. The method of claim 1, wherein the ultra-shallow doped layer comprises a depth measured from the semiconductor surface of less than about 100 Å.

7. The method of claim 1, wherein the substantially inert gas is selected from the group consisting of: argon; nitrogen; xenon; krypton; helium; neon; and radon.

8. The method of claim 1, wherein the dopant is selected from the group consisting of:
antimony; arsenic; arsine; phosphorus; phosphine; and boron.

9. The method of claim 1, further comprising etching away excess dopant from the surface of the semiconductor substrate.

10. The method of claim 1, wherein the acts of energizing ions of the substantially inert gas and directing the energized ions in a beam toward the surface of the semiconductor substrate are accomplished at least in part by using an ion source.

11. The method of claim 10, further comprising forming a monoenergetic ion beam from the energized ions directed toward the surface of the semiconductor substrate.

12. The method of claim 1, further comprising repositioning the semiconductor substrate relative to the beam of energized ions.

13. The method of claim 12, wherein repositioning comprises at least one of translation, tilt, and rotation.

14. The method of claim 1, wherein the act of depositing a thin layer of a dopant comprises depositing a conformal layer of dopant.

15. The method of claim 14, further comprising the step of directing the beam of energized ions with respect to the conformal layer of dopant, such that the ultra-shallow doped layer comprise a substantially uniform thickness.

16. An apparatus for processing a semiconductor substrate comprising:
a processing chamber;
a semiconductor substrate mount configured to support a semiconductor substrate for processing within the processing chamber;
a deposition source configured to form a thin layer of a dopant on a surface of the semiconductor substrate;
an ion accelerating source configured to produce a directional ion beam;
a gas source in fluid communication with the ion accelerating source, the ion accelerating source configured to direct a beam of ions of the substantially inert gas toward the surface of the semiconductor substrate, the beam of ions transferring kinetic energy from the substantially inert gas ions to the thin layer of the dopant, the transfer of energy implanting at least a portion of the thin layer of the dopant into the semiconductor substrate.

17. The apparatus of claim 16, wherein the gas source comprises a substantially inert gas.

18. The apparatus of claim 16, wherein the deposition source is configured for a thin film deposition technique selected from the group consisting of: of physical vapor deposition (PVD); chemical vapor deposition (CVD); electrochemical deposition (ECD); molecular beam epitaxy (MBE); e beam evaporation; sputtering; atomic layer deposition (ALD), and combinations thereof.

19. The apparatus of claim 16, wherein the dopant is selected from the group consisting of:
antimony; arsenic; arsine; phosphorus; phosphine; and boron.

20. The apparatus of claim 16, wherein the ion source includes at least one of a mass selector and an energy selector, such that the ion source provides a substantially monoenergetic ion beam.

21. The apparatus of claim 16, wherein the deposition source and the ion accelerating source are both contained within the same processing chamber.

22. The apparatus of claim 16, further comprising a sequencer in communication with the semiconductor substrate mount, the sequencer configured to move a semiconductor substrate between a deposition position proximal to the deposition source and to an implantation position within the directional ion beam from the ion accelerating source.

23. The apparatus of claim 16, further comprising a positioner in communication with the semiconductor substrate mount, the positioner configured to reposition a semiconductor substrate with respect to at least one of the a deposition source and the directional ion beam.

24. The apparatus of claim 23, wherein the positioner is configured to provide at least one of translation, rotation, and tilt to the semiconductor substrate mount.

25. The apparatus of claim 16, wherein the process chamber and the deposition source are separated by at least one narrow aperture, the separation supporting a substantial pressure differential between the process chamber and the deposition source.

26. The apparatus of claim 25, wherein the narrow aperture is a collimating aperture configured to shape a deposition flux from the deposition source into a substantially linear shape.

27. The apparatus of claim 26, wherein the collimating aperture configured to shape a deposition flux from the deposition source into a shape substantially similar to a shape of the ion beam within a plane containing a semiconductor substrate surface.

28. The apparatus of claim 16, wherein the deposition source comprises a magnetron sputtering system.

29. The apparatus of claim 16, wherein the deposition source comprises an evaporation cell.

30. A method for processing a semiconductor substrate comprising:
a. depositing a monolayer of substantially pure dopant onto a surface of the semiconductor substrate;
b. directing a beam of substantially inert monoenergetic ions toward the deposited monolayer on the surface of the semiconductor substrate, wherein the beam of substantially inert ions drives at least a portion of the monolayer into the semiconductor substrate.

31. The method of claim 30, further comprising repeating the acts of depositing a monolayer and directing a beam of substantially inert monoenergetic ions in succession, responsive to a dosage level being less than a target dosage

32. The method of claim 30, wherein the act of depositing a monolayer of substantially pure dopant comprises thin film deposition technique selected from the group consisting of: of physical vapor deposition (PVD); chemical vapor deposition (CVD); electrochemical deposition (ECD); molecular beam epitaxy (MBE); e-beam evaporation; sputtering; atomic layer deposition (ALD), and combinations thereof.

33. The method of claim 30, wherein the substantially inert monoenergetic ions are selected from the group consisting of argon; nitrogen; xenon; krypton; helium; neon; and radon.

34. The method of claim 30, wherein the substantially pure dopant is selected from the group consisting of: antimony; arsenic; arsine; phosphorus; phosphine; and boron.

35. The method of claim 30, further comprising etching away excess dopant from the surface of the semiconductor substrate.

36. An apparatus for processing a semiconductor substrate comprising:
means for depositing a thin layer of a dopant onto a surface of the semiconductor substrate;
means for energizing ions of a substantially inert gas;
means for directing a beam of energized ions toward the surface of the semiconductor substrate; and
means for transferring kinetic energy from the beam of energized ions to the thin layer of dopant, wherein at least a portion of the thin layer of a dopant is implanted by the transfer of energy into the semiconductor substrate.

37. A method for processing a semiconductor substrate comprising:
providing an ion source including a processing chamber, the ion source configured to produce a directed ion beam; and
positioning a thin film deposition source within the processing chamber, the deposition source configured to deposit a thin layer of a doping species onto a surface of a semiconductor substrate, wherein the directed ion beam is adapted to implant at least a portion of the thin layer of a doping species into the semiconductor substrate when the substrate is positioned within the directed ion beam.
